(19) United States
(12) Patent Application Publication
(10) Pub. No.: US 2026/0113993 A1
(43) Pub. Date: Apr. 23, 2026

(54) NEAR-ZERO DIBL MOSFET OF TWO CHANNEL LENGTHS

(71) Applicant: Murata Manufacturing Co., Ltd., Kyoto (JP)

(72) Inventors: Ali Razavieh, San Diego, CA (US); Sinan Goktepeli, Austin, TX (US); Anil Kumar, Poway, CA (US); Kazuhiko Shibata, San Diego, CA (US); Ping Wing Lai, San Diego, CA (US)

(21) Appl. No.: 19/427,294

(22) Filed: Dec. 19, 2025

Related U.S. Application Data
(63) Continuation of application No. PCT/JP2024/023802, filed on Jul. 1, 2024.
(60) Provisional application No. 63/524,608, filed on Jun. 30, 2023.

(51) Int. Cl. H10D 62/10; H10D 30/60; H10D 62/17; H10D 64/27; H10D 84/83

(52) U.S. Cl. CPC H10D 62/102; H10D 30/605; H10D 62/126; H10D 62/235; H10D 64/519; H10D 84/83125

(57) ABSTRACT

A semiconductor device includes a field effect transistor (FET). The FET includes a gate electrode in a gate layer. The gate electrode has a first gate length and a second gate length. The second gate length is greater than the first gate length. The FET also includes an active region in a active region layer. The active region includes a source region and a drain region. The active region layer is beneath the gate layer. The FET has a first channel under the gate electrode having the first gate length and between the source region and the drain region. The FET also has a second channel under the gate electrode having the second gate length and between the source region and the drain region.

### CROSS REFERENCE TO RELATED APPLICATIONS

This application is a continuation of International Patent Application No. PCT/JP2024/023802 filed Jul. 1, 2024 and entitled “NEAR-ZERO DIBL MOSFET OF TWO CHANNEL LENGTHS” which claims priority to and the benefit of U.S. Provisional Patent Application No. 63/524,608 filed Jun. 30, 2023 and entitled “A NEAR-ZERO DIBL MOSFET OF TWO CHANNEL LENGTHS,” all of which are incorporated herein by reference in their entirety.

### TECHNICAL FIELD

The present disclosure relates to a near-zero drain-induced barrier lowering (DIBL) metal-oxide-semiconductor field-effect transistor (MOSFET), and, more particularly, to a near-zero DIBL MOSFET of two channel lengths.

### BACKGROUND

When the semiconductor technology continues to scale down, MOSFETs have shorter channels than they used to have. These transistors may suffer from short channel effects, such as a drain-induced barrier lowering effect (DIBL). The DIBL effect may result in a reduced threshold voltage when a voltage between a drain and a source of a transistor is at a high voltage level. The threshold voltage may become dependent on the voltage between the drain and the source of the transistor. The DIBL effect may cause leakage currents and unwanted turn-on of the transistor at a voltage below an expected threshold voltage. The leakage currents may decrease battery lifetime for low-power applications. Thus, there is a need to alleviate the DIBL effect in the MOSFETs.

### SUMMARY

Embodiments of the present disclosure may include a near-zero DIBL MOSFET of two channel lengths. In one embodiment, a semiconductor device includes a field effect transistor (FET). The FET includes a gate electrode in a gate layer. The gate electrode has a first gate length and a second gate length. The second gate length is greater than the first gate length. The FET also includes an active region in an active region layer. The active region includes a source region and a drain region. The active region layer is beneath the gate layer. The FET has a first channel under the gate electrode having the first gate length and between the source region and the drain region. The FET also has a second channel under the gate electrode having the second gate length and between the source region and the drain region.

In another embodiment, a semiconductor device includes a field effect transistor (FET). The FET includes a plurality of gate electrodes coupled together in a gate layer. Each of the gate electrodes has a first gate length and a second gate length. The second gate length is greater than the first gate length. The FET includes an active region in an active region layer. The active region includes a plurality of source regions and at least one drain region. The active region layer is beneath the gate layer. The FET has a first channel under each of the gate electrodes having the first gate length and between one of the source regions and corresponding one of the at least one drain region. The FET also has a second channel under each of the gate electrodes having the second gate length and between the one of the source regions and the corresponding one of the at least one drain region.

It is to be understood that the foregoing general description and the following detailed description are exemplary and explanatory only and are not restrictive of the invention, as claimed.

### BRIEF DESCRIPTION OF THE DRAWINGS

FIG. 1 illustrates a layout of an exemplary transistor of two channel lengths, in accordance with some embodiments.

FIG. 2 illustrates a detailed view of the exemplary transistor in FIG. 1, in accordance with some embodiments.

FIG. 3 illustrates a cross-sectional view of the exemplary transistor along a first cutting line in FIG. 2, in accordance with some embodiments.

FIG. 4 illustrates two cross-sectional views of the exemplary transistor along the first cutting line and a second cutting line in FIG. 2, in accordance with some embodiments.

FIG. 5 illustrates a cross-sectional view of the exemplary transistor along a third cutting line in FIG. 2, in accordance with some embodiments.

FIG. 6 illustrates transfer characteristics of an exemplary transistor of two channel lengths, in accordance with some embodiments.

FIG. 7 illustrates device characteristics of an exemplary transistor of two channel lengths in an 80-nanometer semiconductor process, in accordance with some embodiments.

FIG. 8 illustrates device characteristics of an exemplary transistor of two channel lengths in a 120-nanometer semiconductor process, in accordance with some embodiments.

FIG. 9 is a layout of an exemplary multi-finger transistor of two channel lengths, in accordance with some embodiments.

### DETAILED DESCRIPTION

The following disclosure provides many different exemplary embodiments, or examples, for implementing different features of the provided subject matter. Specific simplified examples of components and arrangements are described below to explain the present disclosure. These are, of course, merely examples and are not intended to be limiting. Further, certain features may be omitted from some figures and description for clarity, and it is to be understood that different features from different drawings and/or portions of the specification may be combined in a single embodiment, and the present disclosure contemplates all such embodiments that combine different features from the different drawings and/or portions of the specification. In addition, the present disclosure may repeat reference numerals and/or letters in the various examples. This repetition is for the purpose of simplicity and clarity and does not in itself dictate a relationship between the various embodiments and/or configurations discussed.

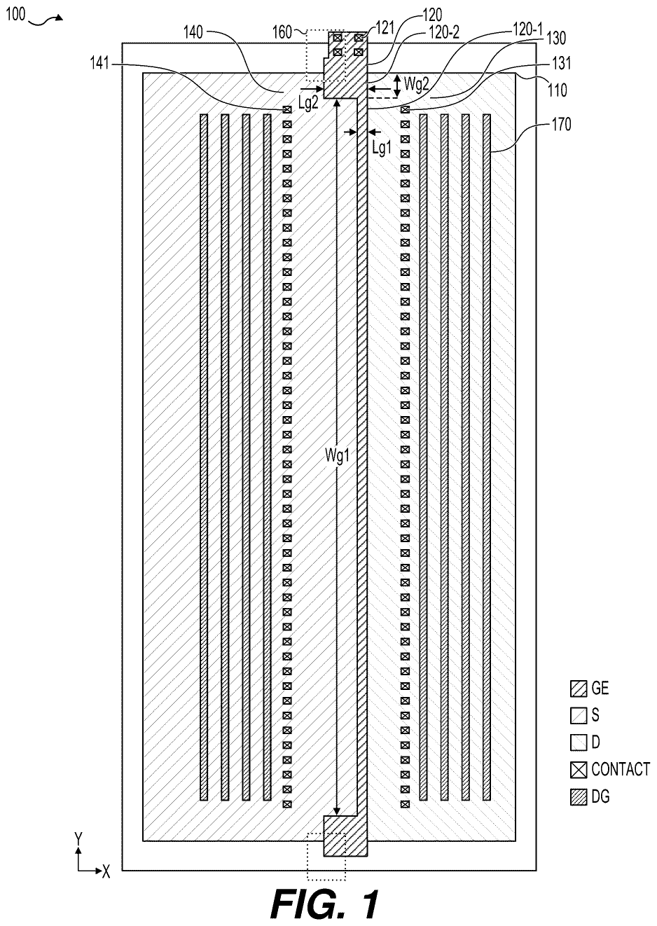

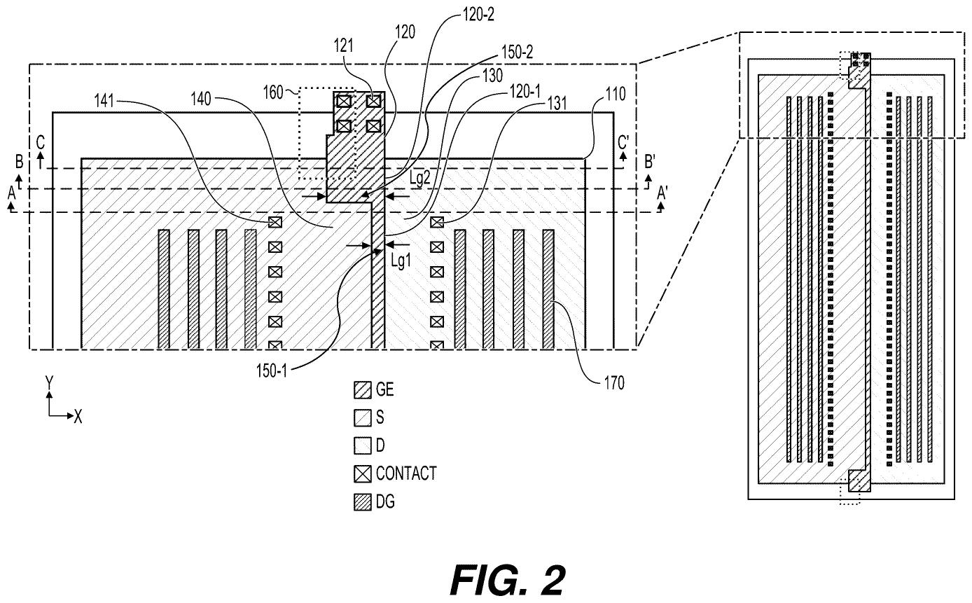

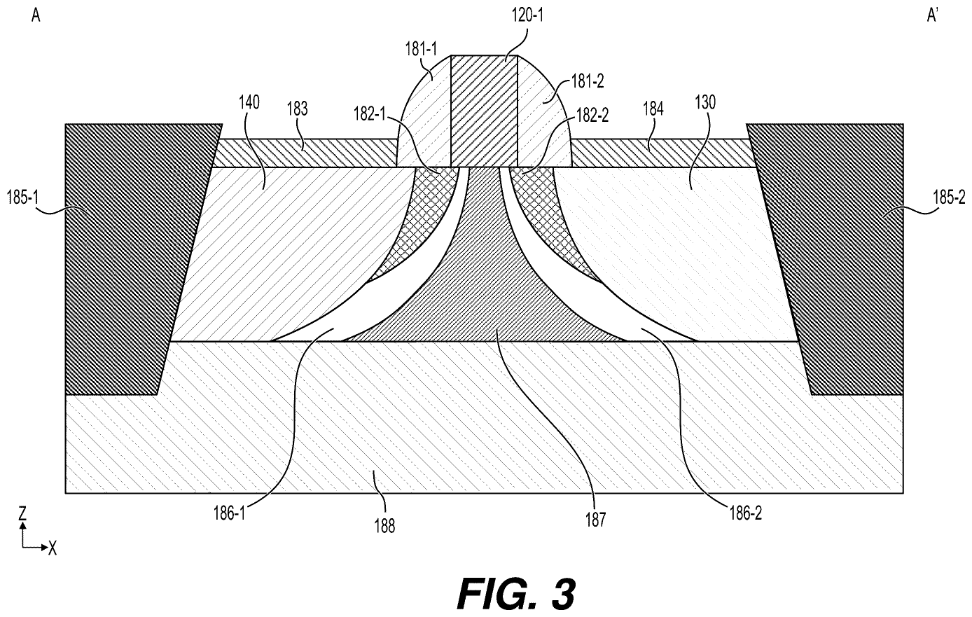

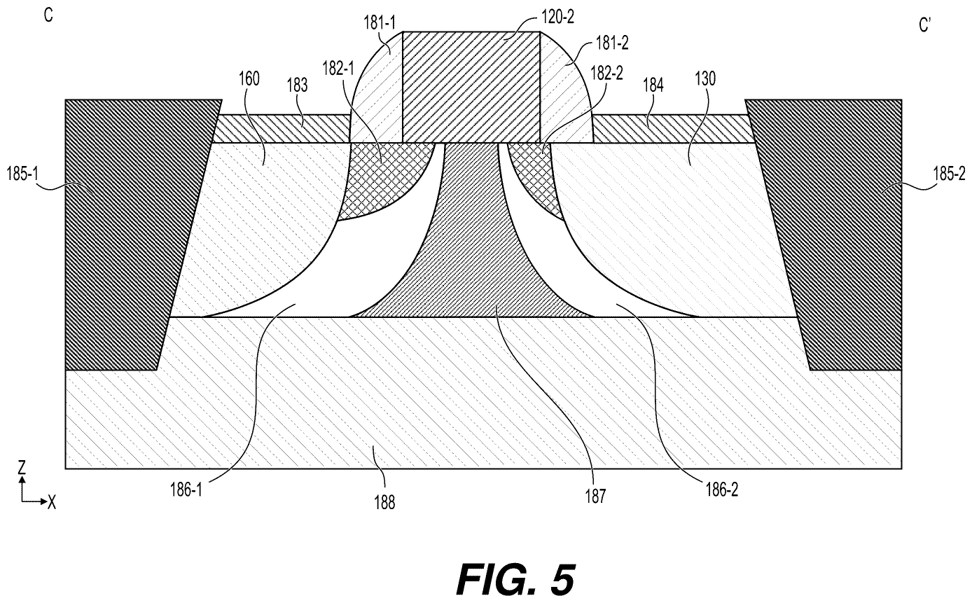

FIG. 1 illustrates a layout of an exemplary transistor 100 of two channel lengths, in accordance with some embodiments. Transistor 100 is a semiconductor device or a part of a semiconductor device. Transistor 100 is a near-zero DIBL MOSFET that has two channel lengths. As shown in FIG. 1, transistor 100 includes a gate electrode (GE) 120, a drain region (D) 130, and a source region(S) 140. Gate electrode 120 is in a gate layer (not shown). Drain region 130 and source region 140 are in an active region 110 in an active region layer (not shown). The active region layer is beneath the gate layer. Transistor 100 also includes one or more contacts 121, 131, and 141 coupled to gate electrode 120, drain region 130, and source region 140, respectively. Transistor 100 may also include a body-tie region 160 (FIG. 1 or 5) that ties source region 140 to a body region 187 (FIG. 3 or 5) of transistor 100. In some embodiments, transistor 100 may include a plurality of dummy gates (DG) 170. Alternatively, in some embodiments, a transistor having two channels (e.g., FIGS. 1 and 2) may not include the dummy gates.

Gate electrode 120 has a first gate length L_{g1} at a first gate region 120-1 and a second gate length L_{g2} at a second gate region 120-2. The second gate length (L_{g2}) is greater than the first gate length (L_{g1}), i.e., L_{g2}>L_{g1}. For example, the first gate length (L_{g1}) may be 80 nanometers (nm) and the second gate length (L_{g2}) may be 480 nm. As another example, the first gate length (L_{g1}) may be 120 nm and the second gate length (L_{g2}) may be 600 nm.

In some embodiments, the second gate length (L_{g2}) is equal to or greater than five times the first gate length (L_{g1}). For example, when the first gate length (L_{g1}) is 80 nm, the second gate length (L_{g2}) may be 480 nm or any other greater length. As another example, when the first gate length (L_{g1}) is 120 nm, the second gate length (L_{g2}) may be 600 nm or any other greater length.

In some embodiments, the second gate length (L_{g2}) is equal to or greater than a predetermined length in a semiconductor process. For example, the second gate length (L_{g2}) may be equal to or greater than the predetermined 480 nm in the 80-nm semiconductor process. As another example, the second gate length (L_{g2}) may be equal to or greater than the predetermined 600 nm in the 120-nm semiconductor process. The predetermined lengths may be determined in accordance with experimental and/or simulation results.

As shown in FIG. 1, gate electrode 120 has first gate region 120-1 (FIG. 1) and second gate region 120-2 (FIG. 1) that are above active region 110 (FIG. 1). Specifically, gate region 120-1 has the first gate length (L_{g1}) and a first gate width (W_{g1}) above active region 110. Gate region 120-2 has the second gate length (L_{g2}) and a second gate width (W_{g2}) above active region 110. The first gate width (W_{g1}) is greater than the second gate width W_{g2}. For example, gate region 120-1 may have the first gate length (L_{g1}) of 80 nm and the first gate width (W_{g1}) of 3,040 nm above active region 110. Gate region 120-2 may have the second gate length (L_{g2}) of 480 nm and the second gate width (W_{g2}) of 380 nm above active region 110. The first gate width (W_{g1}=3,040 nm) is greater than the second gate width (W_{g2}=380 nm). As another example, gate region 120-1 may have the first gate length (L_{g1}) of 120 nm and the first gate width (W_{g1}) of 5,000 nm above active region 110. Gate region 120-2 may have the second gate length (L_{g2}) of 600 nm and the second gate width (W_{g2}) of 600 nm above active region 110. The first width (W_{g1}=5,000 nm) is greater than the second width (W_{g2}=600 nm).

In some embodiments, the first width is equal to or greater than eight times the second width. As described in an example above, gate region 120-1 may have the first gate width (W_{g1}) of 3,040 nm above active region 110. Gate region 120-2 may have the second gate width (W_{g2}) of 380 nm above active region 110. The first gate width (W_{g1}=3,040 nm) is equal to eight times the second gate width (W_{g2}=380 nm). As described in another example above, gate region 120-1 may have the first gate width (W_{g1}) of 5,000 nm above active region 110. Gate region 120-2 may have the second gate width (W_{g2}) of 600 nm above active region 110. The first gate width (W_{g1}=5,000 nm) is greater than eight times the second gate width (W_{g2}=600 nm).

In some embodiments, the second width of gate region 120-2 is equal to or greater than a predetermined width in a semiconductor process. For example, in the 80-nm semiconductor process, gate region 120-2 may have a width equal to or greater than a predetermined 320 nm. As another example, in the 120-nm semiconductor process, gate region 120-2 may have a width equal to or greater than 480 nm.

FIG. 2 illustrates a detailed view of exemplary transistor 100 in FIG. 1, in accordance with some embodiments. As described above, gate electrode 120 has two gate lengths (L_{g1} and L_{g2}). Thus, transistor 100 has two channels between source region 140 and drain region 130. As shown in FIG. 2, transistor 100 has a first channel 150-1 under gate electrode 120 having the first gate length (L_{g1}) (i.e., under gate region 120-1) and between source region 140 and drain region 130. In addition, transistor 100 has a second channel 150-2 under gate electrode 120 having the second gate length (L_{g2}) (i.e., under gate region 120-2) and between source region 140 and drain region 130.

When gate electrode 120 is supplied with a voltage, transistor 100 may form first channel 150-1 (FIG. 2) under gate region 120-1 and between source region 140 and drain region 130. First channel 150-1 has a first channel length L_{ch1} (not shown). Because first channel 150-1 is under gate region 120-1 of the first gate length (L_{g1}), the first channel length (L_{ch1}) is equal to or less than the first gate length (L_{g1}). When transistor 100 is implemented using a scaled-down semiconductor process, the first gate length (L_{g1}) shrinks. The first channel length (L_{ch1}) also shrinks. That is, first channel 150-1 may become a short channel when transistor 100 is implemented in the scaled-down semiconductor process.

One or more short channel effects, such as a DIBL effect, may occur at a short channel in a transistor. If a DIBL effect occurs, the DIBL effect may cause that a threshold voltage of the transistor depends on a voltage between a drain and a source of the transistor. The threshold voltage may become lower when the drain-source voltage is at a higher voltage level. As a result, the DIBL effect may cause leakage currents and unwanted turn-on operations of the transistor at a voltage lower than a nominal threshold voltage.

To address potential DIBL and/or other short channel effects, transistor 100 has second channel 150-2. When gate electrode 120 is supplied with the voltage, transistor 100 may also form second channel 150-2 (FIG. 2) under gate region 120-2 and between source region 140 and drain region 130. Second channel 150-2 has a second channel length L_{ch2} (not shown). Because second channel 150-2 is under gate region 120-2 having the second gate length (L_{g2}), the second channel length (L_{ch2}) is equal to or less than the second gate length (L_{g2}). Second channel 150-2 is parallel with first channel 150-1 and is a long channel as compared to first channel 150-1. In some embodiments, second channel 150-2 has a channel length (L_{ch2}) on which a short channel effect does not occur or has ignorable impacts. That is, a transistor having only one channel with the above channel length (L_{ch2}) has an almost constant threshold voltage at all possible drain-source voltages. The threshold voltage of the transistor is independent from the drain-source voltages.

Because second channel 150-2 is a parallel long channel, second channel 150-2 compensates for the potential barrier lowering near source region 140. Thus, second channel 150-2 alleviates the DIBL and/or other short channel effects on transistor 100. Thus, second channel 150-2 may reduce leakage currents and/or avoid unwanted turn-on operations on transistor 100. Second channel 150-2 may also make a threshold voltage Vₜₕ of transistor 100 to be independent from a voltage V_{DS} between drain region 130 and source region 140. The threshold voltage (Vₜₕ) may remain the same or only slightly lower when the drain-source voltage (V_{DS}) is at a higher voltage level. For example, transistor 100 having two channels may have a first threshold voltage (Vₜₕ) of 0.4 V when the drain-source voltage (V_{DS}) is 0.1 V. Transistor 100 may have a second threshold voltage (Vₜₕ) of 0.39 V when the drain-source voltage (V_{DS}) is 1.5 V. The second threshold voltage is only slightly lower than the first threshold voltage. That is, transistor 100 has a threshold voltage that is independent from the drain-source voltage (V_{DS}).

As shown in FIG. 2, there are three cutting lines from A to A', from B to B′, and from C to C′. The cross-sectional views along these cutting lines are described below.

FIG. 3 illustrates a cross-sectional view of exemplary transistor 100 along the cutting line from A to A′ in FIG. 2, in accordance with some embodiments. As shown in FIG. 3, transistor 100 includes gate region 120-1, drain region 130, source region 140, a pair of sidewall filaments 181-1 and 181-2, a source cladding region 183, a drain cladding region 184, a lightly doped shallow source region 182-1, a lightly doped shallow drain region 182-2, a first halo region 186-1, a second halo region 186-2, body region 187, an insulating region 188, and two trenches 185-1 and 185-2.

Source region 140 of transistor 100 may have a first dopant concentration. Drain region 130 of transistor 100 may have a second dopant concentration. In some embodiments, the first dopant concentration is the same as or substantially equal to the second dopant concentration. That is, transistor 100 has a symmetric source and drain structure. Alternatively, in some embodiments, the first dopant concentration is different from the second dopant concentration. That is, transistor 100 has an asymmetric source and drain structure.

As shown in FIG. 3, transistor 100 includes lightly doped shallow source region 182-1 coupled to source region 140. Transistor 100 also includes lightly doped shallow drain region 182-2 coupled to drain region 130. When source region 140 and drain region 130 include n-type dopants, lightly doped shallow source region 182-1 and drain region 182-2 also include n-type dopants. The n-type dopants may be Arsenic (As), Phosphorus (P), or other n-type dopants. The concentrations of lightly doped shallow source and drain regions 182-1 and 182-2 may be, for example, 8E14 atoms/cm³ in vertical doping and 6E14 atoms/cm³ in 10-degree tilt doping with 4 KeV (i.e., 4×10³ electronic volts). The notation 8E14 represents 8×10¹⁴ and 6E14 represents 6×10¹⁴. This notation is used herein. The concentrations of source region 140 and drain region 130 may be, for example, 1.5E15 atoms/cm³. The concentrations of lightly doped shallow source and drain regions 182-1 and 182-2 are lighter than the concentrations of source region 140 and drain region 130. Lightly doped shallow source and drain regions 182-1 and 182-2 are mostly overlap with source region 140 and drain region 130 in their shallow layers, respectively, and further extend towards the other under gate electrode 120. Lightly doped shallow source and drain regions 182-1 and 182-2 result in reduced peak electric field at drain region 130. It may alleviate a hot carrier effect, DIBL effect, and/or other short channel effects.

As shown in FIG. 3, transistor 100 also includes halo region 186-1 coupled to source region 140 and halo region 186-2 coupled to drain region 130. When source region 140 and drain region 130 include n-type dopants, halo regions 186-1 and 186-2 include p-type dopants. The p-type dopants may be Boron (B). The concentrations of halo regions 186-1 and 186-2 may be, for example, 3E13 atoms/cm³ doped using 10 KeV. Halo regions 186-1 and 186-2 may avoid a punch-through effect, the DIBL effect, and other short channel effects in transistor 100.

Transistor 100 includes body region 187 that has a lightly doped region for forming first channel 150-1 and second channel 150-2. Transistor 100 also includes insulating region 188 that reduces parasitic capacitance within transistor 100. Transistor 100 may be an silicon on insulator (SOI) semiconductor device.

In some embodiments, a transistor having two channels (e.g., channels 150-1 and 150-2 in FIG. 2) may not include lightly doped shallow drain/source regions and halo regions. In some embodiments, a transistor having two channels (e.g., channels 150-1 and 150-2 in FIG. 2) may include lightly doped shallow drain/source regions but may not include halo regions. In some embodiments, a transistor having two channels (e.g., channels 150-1 and 150-2 in FIG. 2) may include halo regions but may not include lightly doped shallow drain/source regions.

Transistor 100 may also include other regions, such as a gate oxide region below gate electrode 120. These regions are not described but may be part of the semiconductor devices herein.

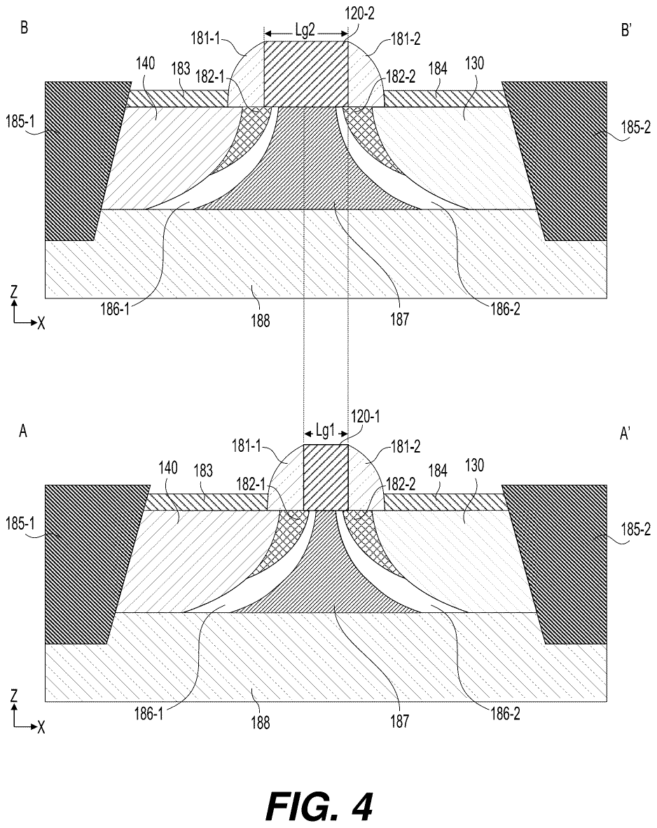

FIG. 4 illustrates two cross-sectional views of exemplary transistor 100 along the cutting line from A to A′ and the cutting line from B to B′ in FIG. 2, in accordance with some embodiments. In FIG. 4, the lower part includes the cross-sectional view that is the same as that shown in FIG. 3. All regions in the lower cross-sectional view are explained in the description above with reference to FIG. 3. The upper part includes the cross-sectional view along the cutting line from B to B′ (FIG. 2). Most regions in the upper cross-sectional view having the same reference numbers are explained in the description above with reference to FIG. 3.

As shown at the upper part of FIG. 4, the cross-sectional view along the cutting line from B to B′ includes gate region 120-2 that has the second gate length (L_{g2}). The lower cross-sectional view includes the cross-sectional view of gate region 120-1 that has the first gate length (L_{g1}). The second gate length (L_{g2}) is greater than the first gate length (L_{g1}), as shown in FIG. 4 and described above with reference to FIGS. 1 and 2.

FIG. 5 illustrates a cross-sectional view of exemplary transistor 100 along the cutting line from C to C′ in FIG. 2, in accordance with some embodiments. As shown in FIG. 5, the cross-sectional view includes most regions shown at the upper part of FIG. 4, except source region 140. Those regions having the same reference numbers are explained in description above with reference to FIG. 3. In FIG. 5, the cross-sectional view includes body-tie region 160 that is conductively coupled between body region 187 and source cladding region 183. As a result, body region 187 is tied to source region 140. That is, transistor 100 includes a body-tied-to-source (BTS) structure.

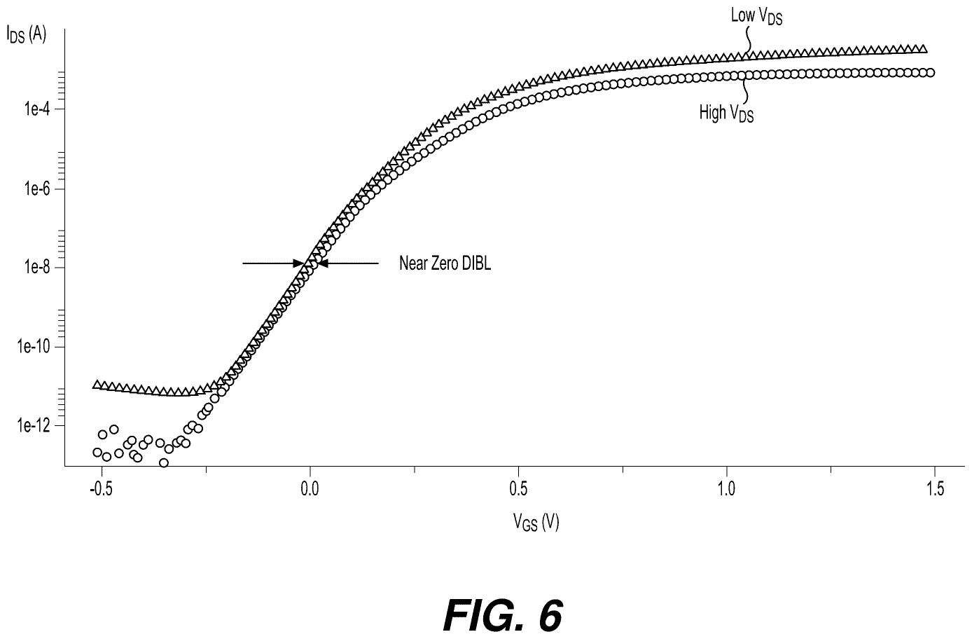

FIG. 6 illustrates transfer characteristics of exemplary transistor 100 of two channel lengths, in accordance with some embodiments. As shown in FIG. 6, a current I_{DS} between drain region 130 and source region 140 increases first and then enters a saturated level when a voltage V_{GS} at gate electrode 120 gradually increases from 0 volt to 1.5 volts. The two curves illustrate I_{DS} values at different V_{GS} values when the voltage V_{DS} between drain region 130 and source region 140 is at low and high voltage levels (e.g., 0.1 and 1.2 volt). As shown in FIG. 6, the curve for high V_{DS} has a near-zero DIBL effect. That is, the high voltage (V_{DS}) causes a near-zero volage decrease in the voltage (V_{GS}) that results in the same current (I_{DS}) value (e.g., 1E−8 Ampere (A)) as the voltage V_{GS} required by the low voltage (V_{DS}).

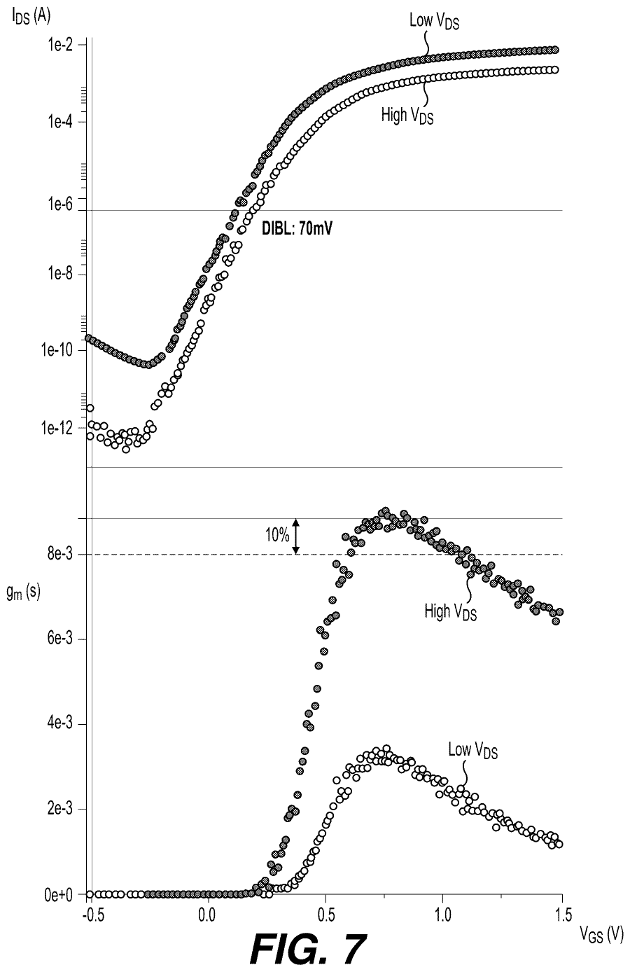

FIG. 7 illustrates device characteristics of exemplary transistor 100 of two channel lengths in an 80-nanometer semiconductor process, in accordance with some embodiments. An exemplary acceptable current I_{DS} may be set at 1E−6 A for transistor 100 to be considered turned off. As shown at the upper part of FIG. 7, transistor 100 has a DIBL value of 70 millivolts (mV) when drain region 130 is supplied with a high voltage level (high V_{DS}). A floating body MOSFET supplied with the same high voltage to its drain region may have a DIBL value of 170 mV. Transistor 100 has less than half of the DIBL value of the floating body MOSFET.

As shown at the lower part of FIG. 7, transistor 100 has a transconductance gₘ value of about 8.8E−3 Siemens(S) when drain region 130 is supplied with the high voltage level (high V_{DS}). The floating body MOSFET supplied with the same high voltage to its drain region may have a transconductance value of about 8E−3 S. Transistor 100 has the transconductance (gₘ) that is about 10 % higher than that of the floating body MOSFET.

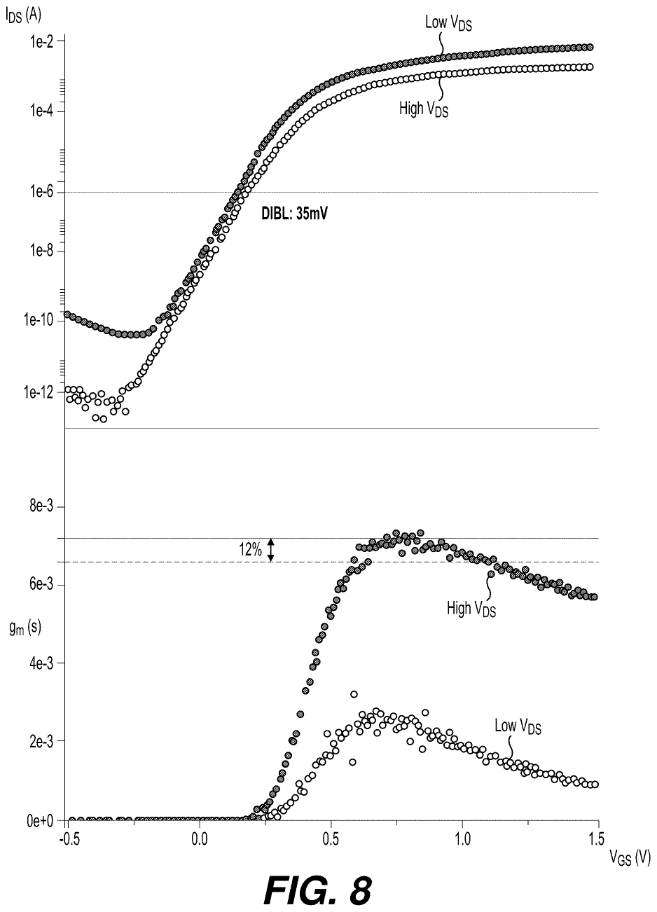

FIG. 8 illustrates device characteristics of exemplary transistor 100 of two channel lengths in a 120-nanometer semiconductor process, in accordance with some embodiments. An exemplary acceptable current I_{DS} may be set at 1E−6 A for transistor 100 to be considered turned off. As shown at the upper part of FIG. 8, transistor 100 has a DIBL value of 35 millivolts (mV) when drain region 130 is supplied with a high voltage level (high V_{DS}). A floating body MOSFET supplied with the same high voltage to its drain region may have a DIBL value of 105 mV. Transistor 100 has only a third of the DIBL value of the floating body MOSFET.

As shown in the lower part of FIG. 8, transistor 100 has a transconductance gₘ value of about 7.4E−3 S when drain region 130 is supplied with the high voltage level (high V_{DS}). The floating body MOSFET supplied with the same high voltage to its drain region may have a transconductance value of about 6.6E−3 S. Transistor 100 has the transconductance (gₘ) that is about 12 % higher than that of the floating body MOSFET.

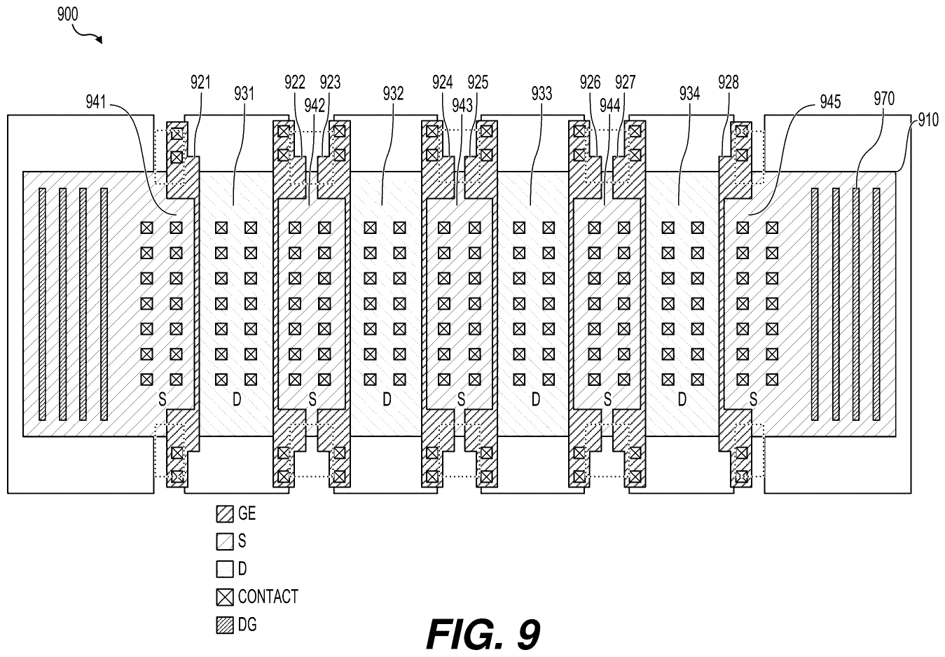

FIG. 9 is a layout of an exemplary multi-finger transistor 900 of two channel lengths, in accordance with some embodiments. As shown in FIG. 9, multi-finger transistor 900 includes gate electrodes 921, 922, 923, 934, 925, 926, 927, and 928 in a gate layer (not shown); source regions 941, 942, 943, 944, and 945 within an active region 910; and drain regions 931, 932, 933, and 934 within active region 910. Active region 910 is in an active region layer (not shown) that is beneath the gate layer. In multi-finger transistor 900, all gate electrodes 921-928 are coupled together (not shown); all source regions 941-945 are coupled together (not shown); and all drain regions 931-934 are coupled together (not shown). Each of gate electrodes 921-928 has a first gate length (e.g., L_{g1} in FIG. 1) and a second gate length (e.g., L_{g2} in FIG. 1), as described above for gate electrode 120 (FIG. 1) with reference to FIGS. 1 and 2. The second gate length is greater than the first gate length.

Multi-finger transistor 900 has a first channel under each of gate electrodes 921-928 having the first gate length (e.g., L_{g1}) and between one of source regions 941-945 and corresponding one of drain regions 931-934. Multi-finger transistor 900 also has a second channel under each of gate electrodes 921-928 having the second gate length (e.g., L_{g2}) and between one of source regions 941-945 and corresponding one of drain regions 931-934.

In some embodiments of multi-finger transistor 900, the second gate length (e.g., L_{g2}) may be equal to or greater than a predetermined length in a semiconductor process, as described above for transistor 100 with reference to FIGS. 1 and 2.

In some embodiments of multi-finger transistor 900, the second gate length (e.g., L_{g2}) may be equal to or greater than five times the first gate length (e.g., L_{g1}), as described above for transistor 100 with reference to FIGS. 1 and 2.

In some embodiments of multi-finger transistor 900, each of gate electrodes 921-928 includes a first gate region having the first gate length and a first gate width and being above active region 910. Each of gate electrodes 921-928 also includes a second gate region having the second gate length and a second gate width and being above active region 910. The first gate width is greater than the second gate width. For example, each of gate electrodes 921-928 may include a first gate region like gate region 120-1 (FIGS. 1 and 2) and a second gate region like gate region 120-2. The first gate region may have a first gate length (e.g., L_{g1}) and a first gate width (e.g., W_{g1}). The second gate region may have a second gate length (e.g., L_{g2}) and a second gate width (e.g., W_{g2}). The first gate width (e.g., W_{g1}) is greater than the second gate width (e.g., W_{g2}), as described above for transistor 100 with reference to FIGS. 1 and 2.

In some embodiments of multi-finger transistor 900, the first gate width (e.g., W_{g1}) may be equal to or greater than eight times the second gate width (e.g., W_{g2}), as described above for transistor 100 with reference to FIGS. 1 and 2.

In some embodiments of multi-finger transistor 900, the second gate width (e.g., W_{g2}) may be equal to or greater than a predetermined gate width in a semiconductor process, as described above for transistor 100 with reference to FIGS. 1 and 2.

In some embodiments, multi-finger transistor 900 includes a plurality of body regions. Each of the body regions is conductively coupled to one of source regions 941-945. For example, multi-finger 900 may have eight body regions beneath gate electrodes 921-928, similar to body region 187 (FIGS. 3, 4, or 5). Each of the eight body regions is conductively coupled to one of source regions 941-945 by a body-tie region, as described above for transistor 100 by body-tie region 160 with reference to FIG. 5.

In some embodiments, multi-finger transistor 900 may include a plurality of lightly doped shallow source regions, similar to lightly doped shallow source region 182-1 (FIG. 3), coupled to each of source regions 941-945, respectively. Multi-finger transistor 900 may also include a plurality of lightly doped shallow drain regions, similar to lightly doped shallow drain region 182-2 (FIG. 3), coupled to each corresponding one of drain regions 931-934.

In some embodiments, multi-finger transistor 900 may include a plurality of first halo regions, similar to halo region 186-1 (FIG. 3). Each of the first halo regions is coupled to one of source regions 941-945. Multi-finger transistor 900 may also include a plurality of second halo regions, similar to halo region 186-2 (FIG. 3). Each of the second halo regions is coupled to one of drain regions 931-934.

In some embodiments, multi-finger transistor 900 may have a threshold voltage that is independent from a voltage between drain regions 931-934 and source regions 941-945, as described above for transistor 100.

In some embodiments, multi-finger transistor 900 may have a plurality of dummy gates 970 in the gate layer. Alternatively, in some embodiments, a multi-finger transistor having two channels may not include the dummy gates.

In the above embodiments, transistors 100, 900, and other transistors having two channels can be an n-type or p-type MOSFET. The dopants described above should be changed accordingly when transistors 100, 900, and other transistors are a p-type MOSFET.

As discussed above, transistors 100, 900, and other transistors have a gate electrode (e.g., gate electrode 120 (FIG. 1 or 2) or gate electrodes 921-928 (FIG. 9)) that includes the first gate length (e.g., L_{g1}) and the second gate length (e.g., L_{g2}). The gate electrode having the second gate length (e.g., gate region 150-2) looks like a hammerhead section and operates as a parallel long-channel device that compensates the potential barrier lowing near the source region(s). The hammerhead section of the gate electrode may result in a constant or near constant threshold voltage (e.g., Vₜₕ) in transistors 100, 900, and other transistors discussed above. It may also eliminate or alleviate the DIBL effect on the transistors 100, 900, and other transistors.

In some embodiments, the reduced DIBL values, e.g., 70 mV (FIGS. 7) and 35 mV (FIG. 8), may be further reduced to 10 mV, a near-zero value, or zero by using proper concentrations of lightly doped shallow source and drain regions (e.g., lightly doped shallow source region 182-1 and drain region 182-2 (FIG. 3)). Transistors 100, 900, and other transistors may have the zero DIBL using with split doping in the lightly doped shallow source and regions. In some embodiments, subthreshold currents of transistors 100, 900, and other transistors may be further improved by proper concentrations of halo regions and channel regions, e.g., halo regions 186-1 and 186-2 and first and second channels 150-1 and 150-2 (i.e., a channel region in body region 187, beneath gate electrode 120, and between source region 140 and drain region 130).

In some embodiments, transistors 100, 900, and other transistors may have symmetric drain and source regions that include equal concentrations of dopants. Alternatively, in some embodiments, transistors 100, 900, and other transistors may have asymmetric drain and source regions that include different concentrations of dopants.

Transistors 100, 900, and other transistors discussed above have improved electrostatics, fewer parasitics, smaller dimensions, and/or near-zero DIBL values, as compared to conventional floating body devices, BTS devices, or H-gate devices. These transistors have characteristics discussed above that may enable robust device scaling to improve transconductance and packing density and to reduce power consumption and leakage currents. These transistors may be applied to analog circuits and radio frequency circuits. These transistors may be applied to low-power applications, such as wearables, earbuds, pacemakers, pressure sensors, or other application-specific circuits that require low or even no leakage current, and/or low or no drain voltage dependence.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the disclosure disclosed herein. It is also intended that the sequence of steps shown in figures are only for illustrative purposes and are not intended to be limited to any particular sequence of steps. As such, those skilled in the art can appreciate that these steps can be performed in a different order while implementing the same method.

It is appreciated that certain features of the specification, which are, for clarity, described in the context of separate embodiments, may also be provided in combination in a single embodiment. Conversely, various features of the specification, which are, for brevity, described in the context of a single embodiment, may also be provided separately or in any suitable sub-combination or as suitable in any other described embodiments of the specification. Certain features described in the context of various embodiments are not to be considered essential features of those embodiments unless the embodiment is inoperative without those elements.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this disclosure, the term “coupled” may also be termed as “electrically coupled”, and the term “connected” may be termed as “electrically connected”. “Coupled” and “connected” may also be used to indicate that two or more elements cooperate or interact with each other.

While embodiments of the present disclosure may address some challenges and provide some benefits, the stated problems and features herein are intended to be examples and not limit the claims or scope of this disclosure. Indeed, the disclosed embodiments may address challenges and provide benefits not explicitly enumerated.

What is claimed is:

1. A semiconductor device, comprising:
a field effect transistor (FET), the FET comprising:
a gate electrode in a gate layer, the gate electrode having a first gate length and a second gate length, the second gate length being greater than the first gate length; and
an active region in a active region layer, the active region comprising a source region and a drain region, the active region layer being beneath the gate layer;
wherein the FET has
a first channel under the gate electrode of the first gate length and between the source region and the drain region, and
a second channel under the gate electrode of the second gate length and between the source region and the drain region.

2. The semiconductor device of claim 1, wherein the second gate length is equal to or greater than a predetermined length in a semiconductor process.

3. The semiconductor device of claim 1, wherein the second gate length is equal to or greater than five times the first gate length.

4. The semiconductor device of claim 1, wherein the gate electrode comprises:
a first gate region having the first gate length and a first gate width and being above the active region; and
a second gate region having the second gate length and a second gate width and being above the active region,
wherein the first gate width is greater than the second gate width.

5. The semiconductor device of claim 4, wherein the first gate width equal to or greater than eight times the second gate width.

6. The semiconductor device of claim 4, wherein the second gate width is equal to or greater than a predetermined gate width in a semiconductor process.

7. The semiconductor device of claim 1, wherein the FET further comprises:
a body region,
wherein the body region is conductively coupled to the source region.

8. The semiconductor device of claim 1, wherein the FET further comprises:
a lightly doped shallow source region coupled to the source region, and
a lightly doped shallow drain region coupled to the drain region.

9. The semiconductor device of claim 1, wherein the FET further comprises:
a first halo region coupled to the source region, and
a second halo region coupled to the drain region.

10. The semiconductor device of claim 1, wherein the FET has a threshold voltage, wherein the threshold voltage is independent from a voltage between the drain region and the source region.

11. The semiconductor device of claim 1, wherein the FET further comprises:
a plurality of dummy gates in the gate layer.

12. A semiconductor device, comprising:
a field effect transistor (FET), the FET comprising:
a plurality of gate electrodes coupled together in a gate layer, each of the gate electrodes having a first gate length and a second gate length, the second gate length being greater than the first gate length; and
an active region in an active region layer, the active region comprising a plurality of source regions and at least one drain region, the active region layer being beneath the gate layer;
wherein the FET has
a first channel under each of the gate electrodes having the first gate length and between one of the source regions and corresponding one of the at least one drain region, and
a second channel under each of the gate electrodes having the second gate length and between the one of the source regions and the corresponding one of the at least one drain region.

13. The semiconductor device of claim 12, wherein the second gate length is equal to or greater than a predetermined length in a semiconductor process.

14. The semiconductor device of claim 12, wherein the second gate length is equal to or greater than five times the first gate length.

15. The semiconductor device of claim 12, wherein each of the gate electrodes comprises:
a first gate region having the first gate length and a first gate width and being above the active region; and
a second gate region having the second gate length and a second gate width and being above the active region,
wherein the first gate width is greater than the second gate width.

16. The semiconductor device of claim 15, wherein the first gate width is equal to or greater than eight times the second gate width; and/or. wherein the second gate width is equal to or greater than a predetermined gate width in a semiconductor process.

17. The semiconductor device of claim 12, wherein the FET further comprises:
a plurality of body regions,
wherein each of the body regions is conductively coupled to one of the source regions.

18. The semiconductor device of claim 12, wherein the FET further comprises:
a plurality of lightly doped shallow source regions, each of the lightly doped shallow source regions being coupled to one of the source regions, and
a plurality of lightly doped shallow drain regions, each of the lightly doped shallow drain regions being coupled to one of the at least one drain region.

19. The semiconductor device of claim 12, wherein the FET further comprises:
a plurality of first halo regions, each of the first halo regions being coupled to one of the source regions, and
a plurality of second halo regions, each of the second halo regions being coupled to one of the at least one drain region.

20. The semiconductor device of claim 12, wherein the FET has a threshold voltage, wherein the threshold voltage is independent from a voltage between the source regions and the at least one drain region, and wherein the FET further comprises a plurality of dummy gates in the gate layer.
